(19) United States
(12) Patent Application Publication
(10) Pub. No.: US 2015/0060911 A1
(43) Pub. Date: Mar. 5, 2015

(54) OPTOELECTRONIC SEMICONDUCTOR DEVICE AND FABRICATING METHOD THEREOF

(71) Applicant: Unistars Corporation, Hsinchu County (TW)

(72) Inventors: Wen-Cheng CHIEN, Hsinchu City (TW); Tien-Hao HUANG, Taoyuan County (TW); Shang-Yi WU, Hsinchu City (TW)

(73) Assignee: Unistars Corporation, Hsinchu County (TW)

(21) Appl. No.: 14/018,422

(22) Filed: Sep. 5, 2013

(51) Int. Cl. H01L 33/52; H01L 33/00; H01L 33/62

(52) U.S. Cl. CPC H01L 33/52; H01L 33/62; H01L 33/005
USPC 257/98; 438/27

(57) ABSTRACT

An optoelectronic semiconductor device comprises a substrate, at least one solid via plug, at least one optoelectronic semiconductor chip, a phosphor layer and a molding body. The at least one solid via plug penetrates through the substrate. The at least one optoelectronic semiconductor chip has a first electrode aligned to and electrically connected with the solid via plug. The phosphor layer covers at least one surface of the optoelectronic semiconductor chip. The molding body encapsulates the substrate, the optoelectronic semiconductor chip and the phosphor layer. The number of solid valid plugs, substrate surfaces, electrodes, bonding pad on each surface of the substrate for forming each optoelectronic semiconductor device can be, for example, two, respectively.

### FIELD OF THE INVENTION

The present invention relates to a semiconductor package structure and the method for fabricating thereof, and more particularly to an optoelectronic semiconductor device and the method for fabricating thereof.

### BACKGROUND OF THE INVENTION

An optoelectronic semiconductor device that has advantages of low power consumption, low thermal radiation, long life time, high impact resistance, small volume, high reaction speed, mercury-free and providing light with a consistent wavelength has been viewed as the next generation light source as the development of flat panel display technique.

To take a white light-emitting diode (LED) device as an example, a wire bonding process adopted for packaging an LED chip is one of the critical steps to form the LED device. However, since the wire bonding process requires additional space to allow bonding wires connecting the LED chip with bonding pads of a substrate, such as a chip carrier, thus it is unlikely to reduce the volume of the LED device. In addition, when a plurality of the LED chips are arranged as a matrix for performing the package process simultaneously, a greater pitch is required to separate two adjacent LED chips, and the phosphor layer that is subsequently formed to cover the LED chips during the package process may not be evenly formed due to the enlarged gap existing between two adjacent LED chips. As a result, problems of color shift that could deteriorate the performance of the LED device may occur.

Therefore, there is a need of providing an improved optoelectronic semiconductor device and the method for fabricating thereof to obviate the drawbacks encountered from the prior art.

### SUMMARY OF THE INVENTION

In accordance with one aspect, the present invention provides an optoelectronic semiconductor device, wherein the optoelectronic semiconductor device comprises a substrate, a first solid via plug, an optoelectronic semiconductor chip, a phosphor layer and a molding body. The first solid via plug penetrates through the substrate. The optoelectronic semiconductor chip has a first electrode aligned to and electrically connected with the first solid via plug. The phosphor layer covers at least one surface of the optoelectronic semiconductor chip. The molding body encapsulates the substrate, the optoelectronic semiconductor chip and the phosphor layer.

In one embodiment of the present invention, the optoelectronic semiconductor device further comprises a second solid via plug penetrating through the substrate, a first patterned metal layer formed on a first surface of the substrate and a second patterned metal layer formed on a second surface of the substrate, wherein the first surface and the second surface are disposed on two opposite sides of the substrate. The first patterned metal layer has two first bonding pads one of which is aligned to and directly in contact with the first solid via plug, and the other is aligned to and directly in contact with the second solid via plug. The second patterned metal layer has two second bonding pads one of which is aligned to and directly in contact with the first solid via plug, and the other is aligned to and directly in contact with the second solid via plug.

In one embodiment of the present invention, the first electrode is electrically connected to the first solid via plug through the first bonding pad.

In one embodiment of the present invention, the optoelectronic semiconductor device further comprises a carrier board mounted with the substrate and associated with the molding body to isolate the substrate, the optoelectronic semiconductor chip and the phosphor layer from ambient gas.

In one embodiment of the present invention, the carrier board has at least one metal line directly in contact with the second bonding pad.

In one embodiment of the present invention, the optoelectronic semiconductor device further comprises a second solid via plug penetrating through the substrate, aligning and electrically connecting to a second electrode of the optoelectronic semiconductor chip.

In accordance with another aspect, the present invention provides a method for fabricating an optoelectronic semiconductor device, wherein the method comprises steps as follows: Firstly, a substrate and a first solid via plug penetrating through the substrate are provided. A first electrode of an optoelectronic semiconductor chip is then aligned and electrically connected to the first solid via plug. Next, a phosphor layer is formed to cover at least one surface of the optoelectronic semiconductor chip. Subsequently, a molding body is provided to encapsulate the substrate, the optoelectronic semiconductor chip and the phosphor layer.

In one embodiment of the present invention, the provision of the substrate and the first solid via plug further comprises steps of providing a second solid via plug penetrating through the substrate, forming a first patterned metal layer having two first bonding pads on a first surface of the substrate, so as to make one of the two first bonding pads aligning to and directly in contact with the first solid via plug and to make the other aligning to and directly in contact with the second solid via plug, and forming a second patterned metal layer having two second bonding pad on a second surface of the substrate, so as to make one of the two second bonding pads aligning to and directly in contact with the first solid via plug and to make the other aligning to and directly in contact with the second solid via plug, wherein the first surface and the second surface are disposed on two opposite sides of the substrate.

In one embodiment of the present invention, the provision of the substrate and the first solid via plug further comprises step of forming a patterned insulating layer on the first patterned metal layer to expose the first bonding pad.

In one embodiment of the present invention, the step of aligning and electrically connecting the first electrode to the first solid via plug comprises connecting the first electrode with the first bonding pad by a solder ball.

In one embodiment of the present invention, the method for fabricating the optoelectronic semiconductor device further comprises mounting the substrate with a carrier board, so as to electrically connect the second bonding pad with a metal line of the carrier board.

In one embodiment of the present invention, the step of mounting the substrate with the carrier board comprises connecting the second bonding pad with the metal line of the carrier board by a solder ball.

In one embodiment of the present invention, the step of encapsulating the substrate, the optoelectronic semiconductor chip and the phosphor layer comprises covering the substrate, the optoelectronic semiconductor chip, the phosphor layer and a portion of the carrier board with the molding body, so as to isolate the substrate, the optoelectronic semiconductor chip and the phosphor layer from ambient air.

In one embodiment of the present invention, the method for fabricating the optoelectronic semiconductor device further comprises providing a second solid via plug penetrating through the substrate in a manner of aligning and electrically connecting to a second electrode of the optoelectronic semiconductor chip.

In accordance with the aforementioned embodiments of the present invention, an optoelectronic semiconductor device and a method for fabricating the optoelectronic semiconductor device are provided; wherein a flip chip bonding process is adopted for aligning and electrically connecting an electrode of an optoelectronic semiconductor chip to a solid via plug penetrating through a substrate; a phosphor layer is then formed on at least one surface of the optoelectronic semiconductor chip and the substrate, the optoelectronic semiconductor chip and the phosphor layer are subsequently encapsulated by a molding body.

In comparison with the conventional optoelectronic semiconductor device packaged by a wire bonding process that requires additional bonding space for lateral extension, the optoelectronic semiconductor device of the present invention packaged by a flip chip bonding process has a package structure with a smaller size. Therefore the features, objects and advantages provided by the embodiments of the present invention are contributable to the minimization of the optoelectronic semiconductor device.

In addition, because of the optoelectronic semiconductor device of the present invention has a package size smaller than that of a conventional optoelectronic semiconductor device, thus more optoelectronic semiconductor chips can be compactly arranged in matrix to be packaged and the gap existing between two adjacent optoelectronic semiconductor chips can be reduced. As a result, the phosphor layer can be formed to cover each of the optoelectronic semiconductor chips more evenly, and problems of color shift would be solved. Moreover, since the optoelectronic semiconductor device is packaged by a flip chip bonding process adopting solder balls to connect the solid via plugs with the optoelectronic semiconductor chip, thus heat generated from the optoelectronic semiconductor chip can be effectively dispersed outwards by the solder balls and the solid via plugs. Therefore the performance of the optoelectronic semiconductor device can be further improved.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A-1G are cross-sectional views of intermediate stages in fabricating an optoelectronic semiconductor device in accordance with one embodiment of the present invention;

FIG. 2 illustrates a cross-sectional view of a plurality of optoelectronic semiconductor chips arranged as a matrix and fixed on a carrier board for being covered with a phosphor layer in accordance with another embodiment of the present invention; and

FIG. 3 illustrates a cross-sectional view of an optoelectronic semiconductor device in accordance with one embodiment of the present invention.

### DETAILED DESCRIPTION OF PREFERRED EMBODIMENTS

An optoelectronic semiconductor device with a reduced package size and a method for fabricating thereof are provided by the present invention in order to improve the uniformity of a phosphor layer covering an optoelectronic semiconductor chip of the optoelectronic semiconductor device, so as to solve the problems of color shift due to the uneven coating of the phosphor layer. The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

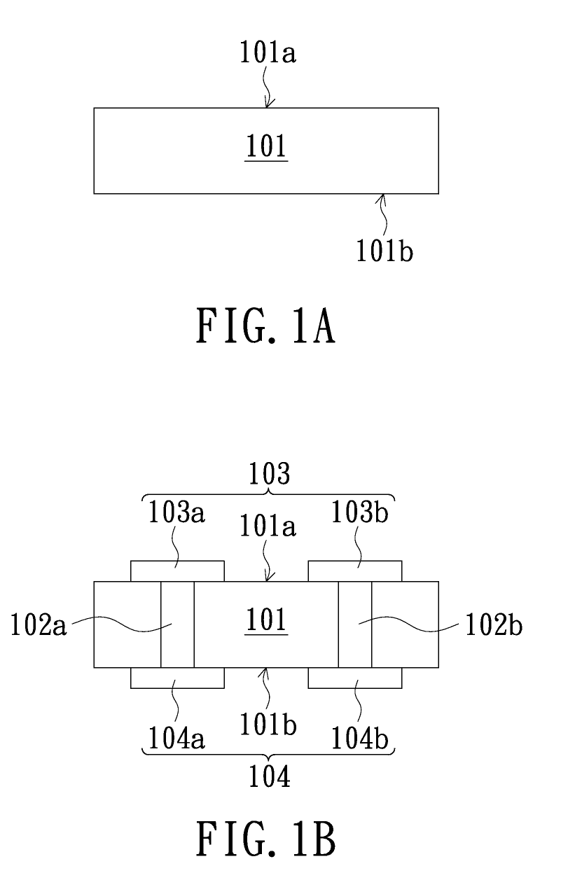

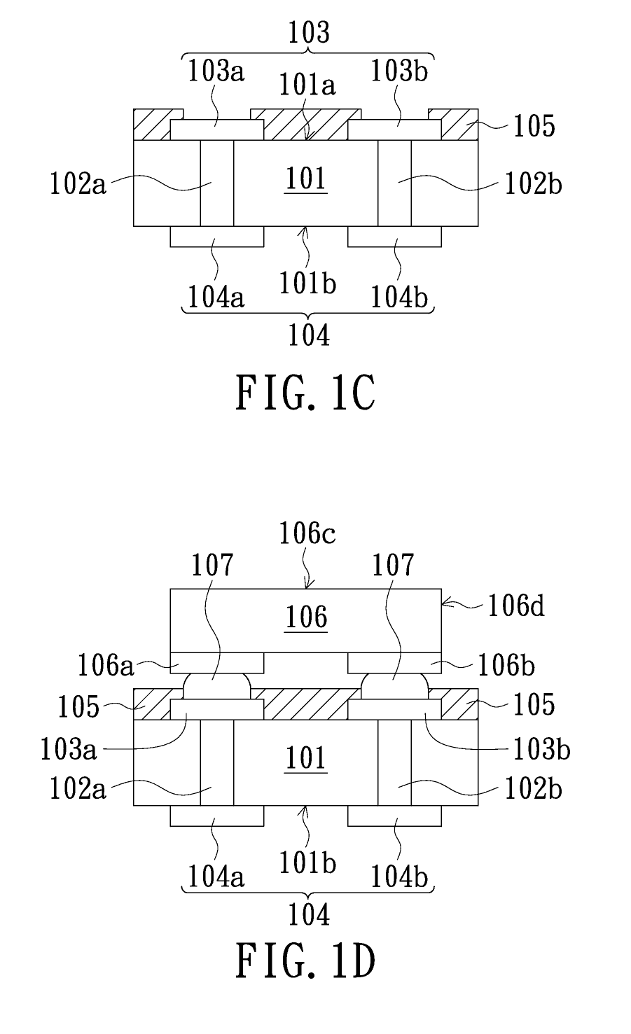

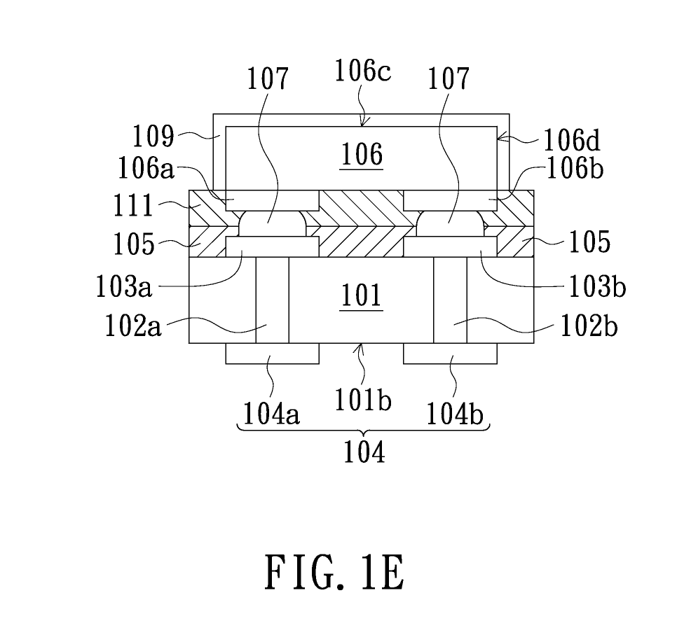

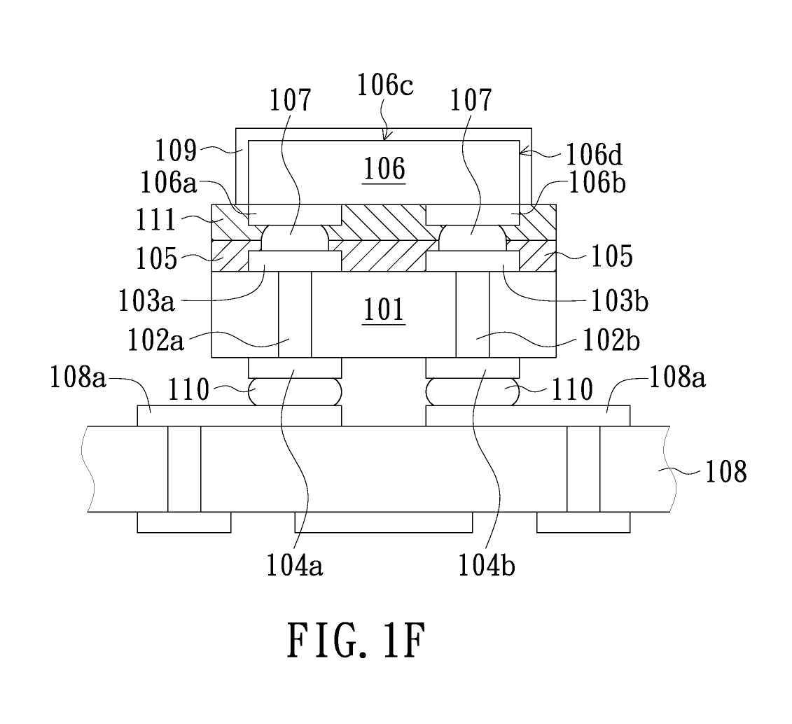

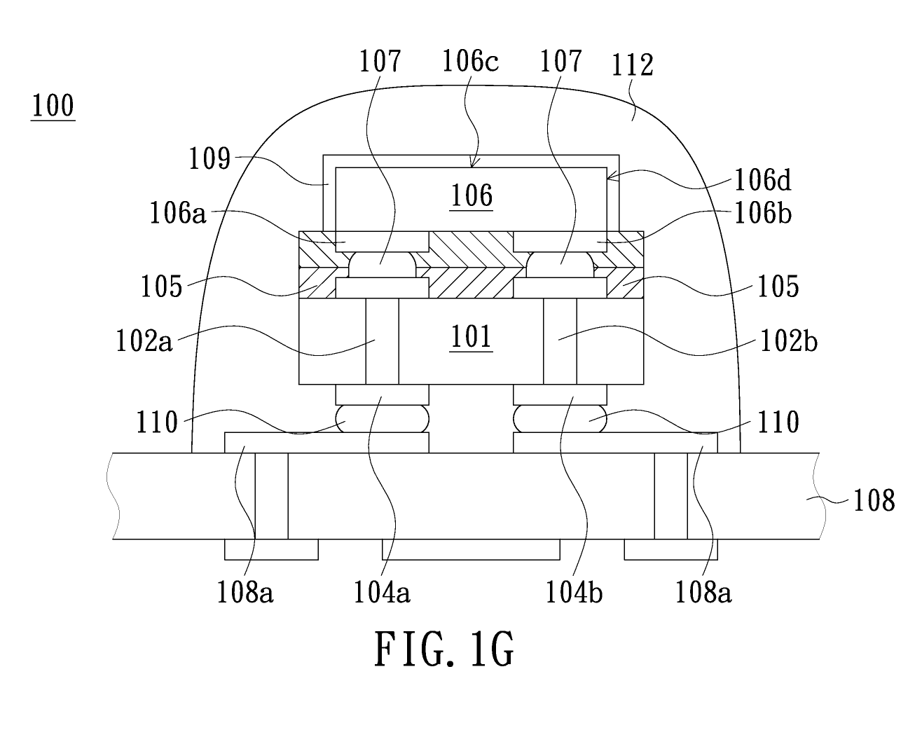

FIGS. 1A-1G are cross-sectional views of intermediate stages in a method for fabricating an optoelectronic semiconductor device 100 in accordance with one embodiment of the present invention, wherein the method for fabricating the optoelectronic semiconductor device 100 comprises steps as follows:

Firstly, a substrate 101 having a first surface 101a and a second surface 101b is provided, wherein the first surface 101a and the second surface 101b are disposed on two opposite sides of the substrate 101 (see FIG. 1A). In some embodiments of the present invention, the substrate 101 may be a lead frame, a printed circuit board (PCB), a flexible PCB, a ceramic substrate or any type of die carrier. In the present embodiment, the substrate 101 is a PCB made of bismaleimide-triazine (BT) resin or the like.

Next, at least one solid via plug, such as a plurality of solid via plugs, namely, a first solid via plug 102a and a second solid via plug 102b, penetrating through the substrate 101 are formed (see FIG. 1B). In the present embodiment, the first and second solid via plugs 102a and 102b are metal via plugs made of aluminum (Al) or copper (Cu).

A first patterned metal layer 103 having at least one bonding pad is then formed on the first surface 101a of the substrate 101; and a second patterned metal layer 104 having at least one bonding pad is then formed on the second surface 101b of the substrate 101. As shown in the illustrated embodiment, the first patterned metal layer 103 has two first bonding pads 103a and 103b; and the second patterned metal layer 104 has two second bonding pads 104a and 104b. In the present embodiment, one of these two first bonding pads, such as the first bonding pad 103a is aligned to and directly in contact with the first solid via plugs 102a; and the other, the first bonding pad 103b is aligned to and directly in contact with the second solid via plugs 102b. One of these two second bonding pads, such as the second bonding pad 104a is aligned to and directly in contact with the first solid via plugs 102a; and the other second bonding pad 104b is aligned to and directly in contact with the second solid via plugs 102b (as shown in FIG. 1B).

It should be appreciated that, although the first and second solid via plugs 102a and 102b, in the present embodiment, are formed prior to the forming of the first and second patterned metal layers 103 and 104, but the process sequences thereof are not limited. In some other embodiment, the first and second patterned metal layers 103 and 104 may be formed on the first surface 101a and the second surface 101b respectively, and the first and second solid via plugs 102a and 102b are subsequently formed in a manner of penetrating through the substrate 101 and directly in contact with the first and second patterned metal layers 103 and 104.

After the first bonding pads 103a and 103b are formed, a patterned insulation layer 105 may be optionally formed on the patterned metal layer 103 and exposing the first bonding pads 103a and 103b (see FIG. 1C). In some embodiments of the present invention, the patterned insulation layer 105 may be made of silicon dioxide (SiO₂), silicon nitride (SiN), silicon carbonitride (SiCN), epoxy resin or other similar insulation materials. In some other embodiments of the present invention, the patterned insulation layer 105 alternatively can be omitted, thus the first bonding pads 103a and 103b are defined directly on the exposed patterned metal layers 103 for the purpose of reducing the manufacturing costs of the optoelectronic semiconductor device 100.

At least one optoelectronic semiconductor chip 106 having a first electrode 106a and a second electrode 106b is then provided in a manner of aligning and electrically connecting the first electrode 106a and the second electrode 106b to the first and second solid via plugs 102a and 102b, respectively (see FIG. 1D). In some embodiments of the present invention, the optoelectronic semiconductor chip 106 may be an LED chip, an organic light-emitting diode (OLED) chip, a laser diode chip, a photo diode chip, a charge-coupled device (CCD) chip or a solar cell chip. In the present embodiment, the optoelectronic semiconductor chip 106 is an LED chip having a cathode electrode and an anode electrode (such as the first electrode 106a and the second electrode 106b) disposed at the same side of the LED chip.

And, in the present embodiment, the method of respectively aligning and electrically connecting the first electrode 106a and the second electrode 106b to the first and second solid via plugs 102a and 102b comprises steps of disposing the optoelectronic semiconductor chip 106 on the patterned insulation layer 105, and then connecting the first electrode 106a and the second electrode 106b with the exposed first bonding pads 103a and 103b of the first patterned metal layer 103 by two solder balls 107. Because the first bonding pads 103a and 103b are aligned to and directly in contact with the first and second solid via plugs 102a and 102b, thus the first electrode 106a and the second electrode 106b that are aligned to and directly in contact with the first bonding pads 103a and 103b can be aligned and electrically connected to the first and second solid via plugs 102a and 102b, respectively.

A phosphor layer 109 is then formed to cover at least one surface of the optoelectronic semiconductor chip 106. In some embodiments of the present invention, an insulating molded layer 111 is formed to fill the gaps existing among the optoelectronic semiconductor chip 106, the first electrode 106a and the second electrode 106b; and subsequently the phosphor layer 109 is formed on the optoelectronic semiconductor chip 106 to blanket a portion of the one surface of the optoelectronic semiconductor chip 106 that is not covered by the insulating molded layer 111 (see FIG. 1E).

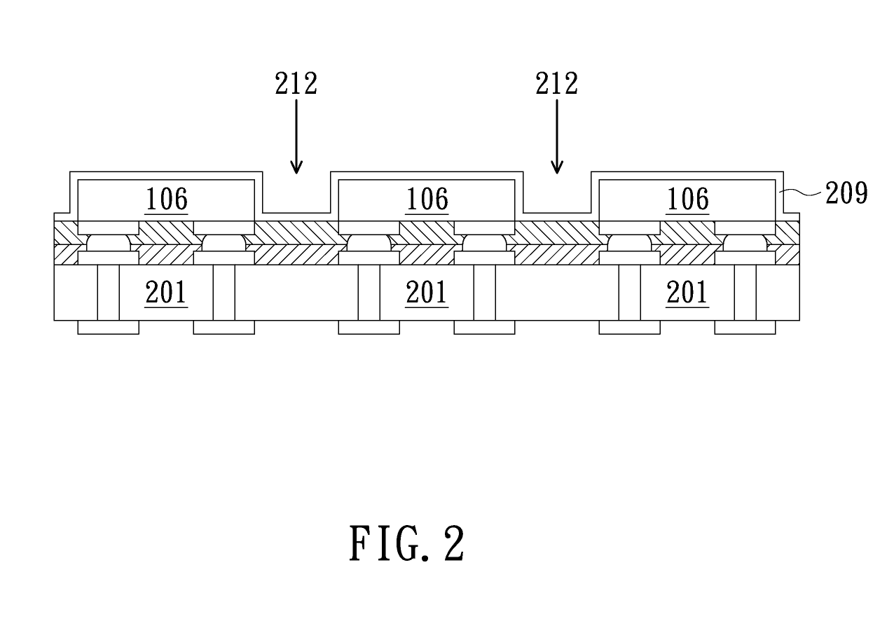

It is worthy to note that the step for forming the phosphor layer 109 can be performed to cover a plurality of the optoelectronic semiconductor chips 106. FIG. 2 is a cross-sectional view illustrating a method for coating a plurality of the optoelectronic semiconductor chips 106 with a phosphor layer 209 in accordance with another embodiment of the present invention. In the present embodiment, a wafer-level-processing technology is adopted to perform the steps depicted in FIG. 1A-1D, so as to fix a plurality of the optoelectronic semiconductor chips 106 arranged as a matrix on the substrate 101. A phosphor layer 209 is then formed by coating on the matrix of the optoelectronic semiconductor chips 106 simultaneously in the same manner as the step of forming the phosphor layer 109 illustrated in FIG. 1E. A wafer dicing process is then performed to form a plurality of package structures similar to that depicted in FIG. 1E

Because the wafer-level-processing technology can arrange the optoelectronic semiconductor chips 106 in more compact matrix arrangement to shorten or reduce the gap existing between two adjacent optoelectronic semiconductor chips 106. As a result, the phosphor layer 209 can be formed to cover each of the optoelectronic semiconductor chips 106 more evenly.

Subsequently, the substrate 101 that is connected to the optoelectronic semiconductor chip 106 is mounted with a carrier board 108. In some embodiments of the present invention, the second bonding pads 104a and 104b of the second patterned metal layer 104 that is formed on the second surface 101b of the substrate 101 are respectively connected to a metal line 108a of the carrier board 108 by two solder balls 110, so as to fix the substrate 101 on the carrier board 108 and electrically connect the optoelectronic semiconductor chip 106 with the carrier board 108 (see FIG. 1F). In some embodiments of the present invention, the carrier board 108 may be a metal core printed circuit board (MCPCB), a ceramic circuit board or a submount board having excellent heat dissipation property.

Since the optoelectronic semiconductor chips 106 are package by a flip chip package process that adopts the solder balls 107 and 110 vertically aligned to and directly in contact with the solid via plugs 102a and 102b to mount the optoelectronic semiconductor chips 106 with the carrier board 108 and make the optoelectronic semiconductor chips 106 electrically connect to the metal line 108a of the carrier board 108, thus the package structure of the optoelectronic semiconductor chips 106 does not necessitate additional space for lateral extension. As a result, the package size of the optoelectronic semiconductor device 100 can be reduced. Moreover, more of the optoelectronic semiconductor chips 106 can be arranged on the carrier board 108 in virtue of the reduced packaging size, thus the packaging density can be also increased.

After the phosphor layer 109 is formed, referring to FIG. 1F again, a molding body 112 is then formed to encapsulate the substrate 101, the optoelectronic semiconductor chip 106, the phosphor layer 109 and a portion of the carrier board 108, so as to isolate the substrate 101, the optoelectronic semiconductor chip 106 and the phosphor layer 109 from ambient gas exposure, and meanwhile, the optoelectronic semiconductor device 100 as shown in FIG. 1G is completed.

In the present embodiment, the optoelectronic semiconductor device 100 comprises the substrate 101, the at least one solid via plug (such as solid via plugs 102a and 102b), the optoelectronic semiconductor chip 106, the phosphor layer 109, the carrier board 108 and the molding body 112. The first solid via plug 102a and the second solid via plug 102b penetrate the substrate 101. The optoelectronic semiconductor chip 106 has at least one electrode, such as first and second electrodes 106a and 106b respectively aligned to and electrically connected with the first and second solid via plugs 102a and 102b. The phosphor layer 109 covers at least one surface of the optoelectronic semiconductor chip 106. The molding body 112 is associated or combined with the carrier board 108 to encapsulate the substrate 101, the optoelectronic semiconductor chip 106 and the phosphor layer 109, so as to isolate the substrate 101, the optoelectronic semiconductor chip 106 and the phosphor layer 109 from ambient gas.

In some embodiments of the present invention, the molding body 112 is composed of epoxy resin, silicon gel, polyimide (PI) or other transparent molding compounds. Typically, the molding body 112 not only serve as a passivation layer used to protect the optoelectronic semiconductor device 100 but also serve as a spherical lens used to enhance the optical characteristics of the optoelectronic semiconductor device 100.

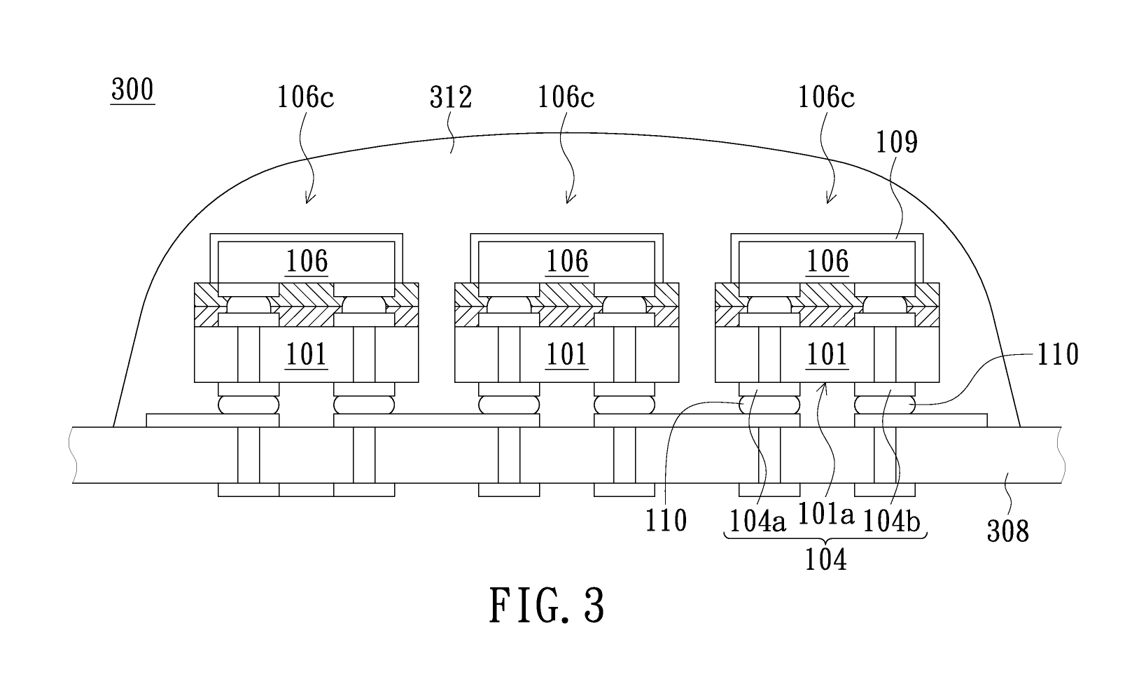

In the present embodiment, although merely one optoelectronic semiconductor chip 106 is arranged to be encapsulated by the molding body 112, but in other embodiments this is not limited to the illustrated embodiment depicted in FIG. 1G. For example, FIG. 3 illustrates a cross-sectional view of an optoelectronic semiconductor device 300 in accordance with one embodiment of the present invention. In the present embodiment, the optoelectronic semiconductor device 300 is formed by continuing from the completion of the structure depicted in FIG. 2, and the device structure of the optoelectronic semiconductor device 300 is similar to that of the optoelectronic semiconductor device 100 depicted in FIG. 1G, except that the spherical lens made from the molding body 312 can encapsulate a plurality of the optoelectronic semiconductor chips 106.

In accordance with the aforementioned embodiments of the present invention, an optoelectronic semiconductor device and a method for fabricating the optoelectronic semiconductor device are provided; wherein a flip chip bonding process is adopted for aligning and electrically connecting an electrode of an optoelectronic semiconductor chip to a solid via plug penetrating through a substrate; a phosphor layer is then formed on at least one surface of the optoelectronic semiconductor chip and the substrate, the optoelectronic semiconductor chip and the phosphor layer are subsequently encapsulated by a molding body.

In comparison with the conventional optoelectronic semiconductor device packaged by a wire bonding process that requires additional bonding space for lateral extension, the optoelectronic semiconductor device of the present invention packaged by a flip chip bonding process has a package structure with a smaller size. Therefore the features, objects and advantages provided by the embodiments of the present invention are contributable to the minimization of the optoelectronic semiconductor device.

In addition, because of the optoelectronic semiconductor device of the present invention has a package size smaller than that of a conventional optoelectronic semiconductor device, thus more optoelectronic semiconductor chips can be arranged in matrix to be packaged and the gap existing between two adjacent optoelectronic semiconductor chips can be reduced. As a result, the phosphor layer can be formed to cover each of the optoelectronic semiconductor chips more evenly, and problems of color shift would be solved. Moreover, since the optoelectronic semiconductor device is packaged by a flip chip bonding process adopting solder balls to connect the solid via plugs with the optoelectronic semiconductor chip, thus heat generated from the optoelectronic semiconductor chip can be effectively dissipated outwards by the solder balls and the solid via plugs. Therefore the performance of the optoelectronic semiconductor device can be further improved.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An optoelectronic semiconductor device, comprising:
a substrate;
a first solid via plug, penetrating through the substrate;
an optoelectronic semiconductor chip, having a first electrode aligned to and electrically connected with the first solid via plug;
a phosphor layer, covers at least one surface of the optoelectronic semiconductor chip; and
a molding body encapsulating the substrate, the optoelectronic semiconductor chip and the phosphor layer.

2. The optoelectronic semiconductor device according to claim 1, further comprising:
a second solid via plug penetrating through the substrate;
a first patterned metal layer, formed on a first surface of the substrate and having two first bonding pads, wherein one of the two first bonding pads is aligned to and directly in contact with the first solid via plug, and the other is aligned to and directly in contact with the second solid via plug; and
a second patterned metal layer, formed on a second surface of the substrate and having two second bonding pads, wherein the first surface and the second surface are disposed on two opposite sides of the substrate, one of the two second bonding pads is aligned to and directly in contact with the first solid via plug, and the other is aligned to and directly in contact with the second solid via plug.

3. The optoelectronic semiconductor device according to claim 2, wherein the first electrode is electrically connected to the first solid via plug through the first bonding pad.

4. The optoelectronic semiconductor device according to claim 2, further comprising a carrier board mounted with the substrate and associated with the molding body to isolate the substrate, the optoelectronic semiconductor chip and the phosphor layer from ambient gas.

5. The optoelectronic semiconductor device according to claim 4, wherein the carrier board has at least one metal line directly in contact with the second bonding pad.

6. The optoelectronic semiconductor device according to claim 1, further comprising a second solid via plug penetrating through the substrate, aligning and electrically connecting to a second electrode of the optoelectronic semiconductor chip.

7. A method for fabricating an optoelectronic semiconductor device comprising steps as follows:
providing a substrate and a first solid via plug penetrating through the substrate;
aligning and electrically connecting a first electrode to the first solid via plug;
forming a phosphor layer on at least one surface of the optoelectronic semiconductor chip; and
providing a molding body to encapsulate the substrate, the optoelectronic semiconductor chip and the phosphor layer.

8. The method according to claim 7, wherein the provision of the substrate and the first solid via plug further comprises steps of:
providing a second solid via plug penetrating through the substrate;
forming a first patterned metal layer having two first bonding pads on a first surface of the substrate, so as to make one of the two first bonding pads aligning to and directly in contact with the first solid via plug and to make the other aligning to and directly in contact with the second solid via plug; and
forming a second patterned metal layer having two second bonding pads on a second surface of the substrate, so as to make one of the two second bonding pads aligning to and directly in contact with the first solid via plug and to make the other aligning to and directly in contact with the second solid via plug, wherein the first surface and the second surface are disposed on two opposite sides of the substrate.

9. The method according to claim 8, wherein the provision of the substrate and the first solid via plug further comprises step of forming a patterned insulation layer on the first patterned metal layer to expose the first bonding pad.

10. The method according to claim 8, wherein the step of aligning and electrically connecting the first electrode to the first solid via plug comprises connecting the first electrode with the first bonding pad by a solder ball.

11. The method according to claim 8, further comprising mounting the substrate with a carrier board, so as to electrically connect the second bonding pad with a metal line of the carrier board.

12. The method according to claim 11, wherein the step of mounting the substrate with the carrier board comprises connecting the second bonding pad with the metal line of the carrier board by a solder ball.

13. The method according to claim 11, wherein the step of encapsulating the substrate, the optoelectronic semiconductor chip and the phosphor layer comprises covering the substrate, the optoelectronic semiconductor chip, the phosphor layer and a portion of the carrier board with the molding body, so as to isolate the substrate, the optoelectronic semiconductor chip and the phosphor layer from ambient air.

14. The method according to claim 7, further comprising step of providing a second solid via plug penetrating through the substrate in a manner of aligning and electrically connecting to a second electrode of the optoelectronic semiconductor chip.
